(19) United States
(12) Patent Application Publication
(10) Pub. No.: US 2015/0147830 A1
(43) Pub. Date: May 28, 2015

(54) DETECTION OF SUBSTRATE DEFECTS BY TRACKING PROCESSING PARAMETERS

(71) Applicant: Applied Materials, Inc., Santa Clara, CA (US)

(72) Inventors: Ilias ILIOPOULOS, Foster City, CA (US); Shuo NA, Sunnyvale, CA (US); Kelby YANCY, Forney, TX (US)

(21) Appl. No.: 14/091,095

(22) Filed: Nov. 26, 2013

(51) Int. Cl. H01L 21/66

(52) U.S. Cl. CPC H01L 22/26; H01L 22/12
USPC 438/17

(57) ABSTRACT

A method comprising processing a substrate exposed to a plasma in a processing chamber, obtaining a metric indicative of a parameter of the plasma during the processing of the substrate, and determining a defect in the substrate by comparing the metric to a predefined criteria.

### BACKGROUND OF THE INVENTION

1. Field of the Invention

Embodiments of the present invention generally relate to a method and system for detecting substrate defects during processing. More specifically, a method and system for detection of substrate breakage by tracking process parameters.

2. Description of the Related Art

Substrate processing systems are used to process substrates, such as silicon wafers in the production of integrated circuit devices as well as large area substrates in the manufacture of flat panel displays, solar collection devices, among other electronic devices. Particularly in the production of flat panel displays, manufacturers face new challenges due to shrinking pixel size, fast refresh rate and reduced substrate thickness. These challenges require manufacturers to improve defect control, film properties and thickness.

Typically, robots are disposed in the substrate processing system to transfer the substrates through a plurality of process chambers for conducting a sequence of processing steps of the fabrication process. The use of robots in the processing of substrates is essential to processing a large number of substrates through many different types of processing technologies with minimal contamination (e.g., substrate handling contamination). To be profitable, these systems feature high processing and transfer speed, and greater accuracy to minimize defects to provide a high throughput system.

One of the key issues facing manufacturers includes glass breakage. A glass breakage incident brings the tool to a costly unscheduled shut down that typically takes 12-18 hrs to correct and may require wet cleaning of the process or transfer chambers. In certain cases, the initial incident contaminates panels processed subsequent to the incident, resulting in defects in the processed panels, and may include scrapping the defective panels. Thus, glass breakage typically results in tool downtime, loss of production, and ultimately the loss of profits for the manufacturer.

What is needed is a method for detecting defects in substrates during processing to minimize defective substrates that would otherwise require scrapping.

### SUMMARY OF THE INVENTION

Embodiments of the invention generally provide a method for determining defects and/or imperfections in substrates during processing by tracking or monitoring processing parameters during processing.

In one embodiment, a method is provided. The method includes processing a substrate exposed to a plasma in a processing chamber, obtaining a metric indicative of a parameter of the plasma during the processing of the substrate, and determining a defect in the substrate by comparing the metric to a predefined criteria.

In another embodiment, a method is provided. The method includes processing a substrate exposed to a plasma in a processing chamber, obtaining a metric indicative of a parameter of the plasma during the processing of the substrate, ceasing the processing when the parameter of the plasma is outside of a predetermined limit indicating a defective substrate, and removing the defective substrate from the processing system.

In another embodiment, a method is provided. The method includes transferring n substrates into one or more chambers in a processing system, plasma processing each of the n substrates sequentially, monitoring parameters of the plasma during plasma processing of the n substrates, ceasing plasma processing when the parameters of one of the n substrates are outside of a predetermined limit indicating a defective substrate, and removing the defective substrate from the processing system.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a top plan view of a multi-chamber substrate processing system.

FIG. 2 is a schematic cross-sectional view of one embodiment of a processing chamber that may be part of the substrate processing system of FIG. 1.

FIG. 3A is a graph comparing a typical Vdc trace with an abnormal Vdc trace during a deposition process.

FIG. 3B is a graph showing deposition runs on four substrates.

FIG. 4 is a graph showing deposition runs on multiple substrates.

FIG. 5 is another graph showing deposition runs on multiple substrates.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein provide a method for determining defects and/or imperfections in substrates during processing by tracking or monitoring processing parameters during processing. Embodiments of the invention are exemplarily described in a processing system available from Applied Materials, Inc., of Santa Clara, Calif., but some embodiments may be successfully practiced in systems available from other manufacturers.

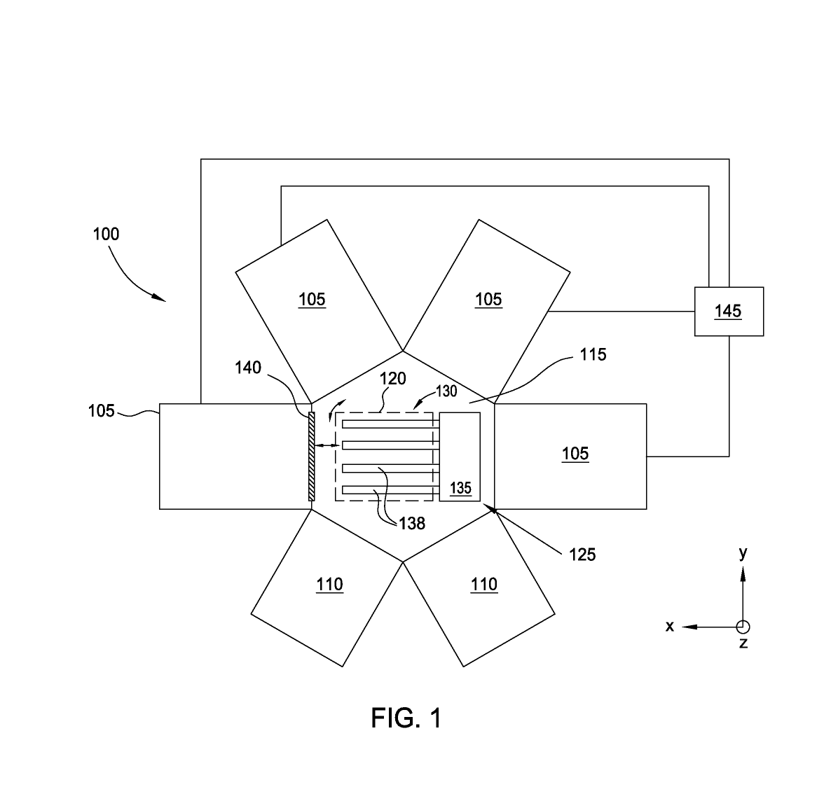

FIG. 1 is a top plan view of a multi-chamber substrate processing system 100 suitable for the fabrication of structures and devices on a large area substrate for use in the fabrication of liquid crystal displays (LCD's), flat panel displays, organic light emitting diodes (OLED's), or photovoltaic cells for solar cell arrays, on flat media. The processing system 100 includes a plurality of processing chambers 105 and one or more load lock chambers 110 positioned around a central transfer chamber 115. The processing chambers 105 may be configured to complete a number of different processing steps to achieve a desired processing of flat media, such as a large area substrate 120 (outlined in dashed lines). The processing chambers 105 may be of any type for performing a plasma process, such as a plasma enhanced chemical vapor deposition (PECVD) chamber, a sputtering chamber, or plasma etching chamber.

Positioned within the transfer chamber 115 is a transfer robot 125 having an end effector 130. The end effector 130 is configured to be supported and move independently of the transfer robot 125 to transfer the substrate 120. The end effector 130 includes a wrist 135 and a plurality of fingers 138 adapted to support the substrate 120. In one embodiment, the transfer robot 125 is configured to be rotated about a vertical axis and/or linearly driven in a vertical direction (Z direction) while the end effector 130 is configured to move linearly in a horizontal direction (X and/or Y direction) independent of and relative to the transfer robot 125. For example, the transfer robot 125 raises and lowers the end effector 130 (Z direction) to various elevations within the transfer chamber 115 to align the end effector 130 with openings 140 (one is shown in FIG. 1) in the processing chambers 105 and the load lock chambers 110. When the transfer robot 125 is at a suitable elevation, the end effector 130 is extended horizontally (X or Y direction) to transfer and/or position the substrate 120 into and out of the openings 140 in any one of the processing chambers 105 and the load lock chambers 110. Additionally, the transfer robot 125 may be rotated to align the end effector 130 with other processing chambers 105 and the load lock chambers 110. A controller 145 may be coupled to the processing system 100 to control and/or monitor processing parameters within the processing system 100.

The trend towards increasingly larger substrates and smaller device features requires increasingly precise positional accuracy of the substrate in the various process chambers 105 in order to ensure repetitive device fabrication with low defect rates. Increasing the positional accuracy of substrates throughout the processing system 100 is a constant challenge. In one example, flat-panel display substrates (e.g., glass substrates) are transferred on the end effector 130 (e.g., a blade or fingers) of the transfer robot 125 to and from the various chambers 105 of the processing system 100. During this transfer it is difficult to ensure that flat-panel display substrates align properly with the end effector 130, and once aligned, that the substrate can pass through the openings 140 in the load lock chambers 110 or the processing chambers 105 without collisions due to a shift in alignment (i.e., misalignment) during transfer. A collision may not only chip or crack the flat-panel display substrate, but also create and deposit debris in the load lock chamber 110, the transfer chamber 115, or the processing chambers 105. Such debris may cause processing defects or other damage to the substrate from which the debris originated as well as subsequently processed substrates. Thus, the presence of debris often requires shutting down the processing system 100, or a portion thereof, to thoroughly remove the potentially contaminating debris. Moreover, with larger dimension substrates and increased device density, the value of each substrate has greatly increased. Accordingly, damage to the substrate or yield loss because of substrate misalignment is highly undesirable due to consequential increase in cost and reduction in throughput.

Embodiments of the processing system 100 described herein alleviate the challenge in identifying glass breakage or debris from glass breakage in the processing system 100. Embodiments of a defect detection method will be explained in conjunction with an exemplary processing chamber 105 and its operation.

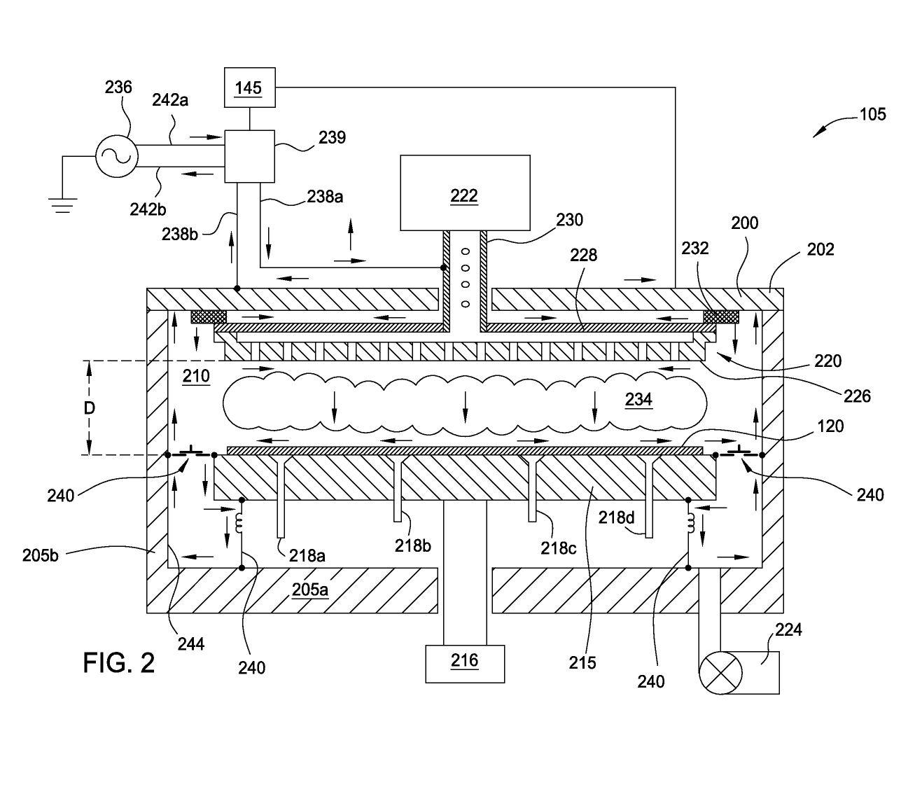

FIG. 2 is a schematic cross-sectional view of one embodiment of a processing chamber 105 that may be part of the substrate processing system 100 of FIG. 1. The processing chamber 105 is configured to process the large area substrate 120 using plasma in forming structures and devices. The substrate 120 may be thin sheet of metal, plastic, organic material, silicon, glass, quartz, or polymer, among other suitable materials. The substrate 120 may have a surface area greater than about 1 square meter, such as greater than about 2 square meters. In other embodiments, the substrate 120 may include a plan surface area of about 15,600 cm², or greater, for example about a 90,000 cm² plan surface area (or greater). The structures may be thin film transistors which may comprise a plurality of sequential deposition and masking steps. Other structures may include p-n junctions to form diodes for photovoltaic cells.

As shown in FIG. 2, the processing chamber 105 generally comprises a chamber body 200 including a lid 202, a bottom 205a and sidewalls 205b that at least partially defines a processing volume 210. A substrate support 215 is disposed in the processing volume 210. The substrate support 215 is adapted to support the substrate 120 on a top surface during processing. The substrate support 215 is coupled to an actuator 216 adapted to move the substrate support at least vertically to facilitate transfer of the substrate 120 and/or adjust a distance D between the substrate 120 and a showerhead assembly 220. One or more lift pins 218a-218b may extend through the substrate support 215. The lift pins 218a-218b are adapted to contact the bottom 205a of the chamber body 200 and support the substrate 120 when the substrate support 215 is lowered by the actuator 216 in order to facilitate transfer of the substrate 120 where the substrate support 215 is lowered allowing the lift pins 218a-218d to contact and support the lower surface of the substrate 120. In a processing position as shown in FIG. 2, the lift pins 218a-218b are adapted to be flush with or slightly below the upper surface of the substrate support 215 to allow the substrate 120 to lie flat on the substrate support 215.

The showerhead assembly 220 is configured to supply a processing gas to the processing volume 210 from a processing gas source 222. The processing chamber 105 also comprises an exhaust system 224 configured to apply negative pressure to the processing volume 210. The showerhead assembly 220 is generally disposed opposing the substrate support 215 in a substantially parallel relationship.

In one embodiment, the showerhead assembly 220 comprises a gas distribution plate 226 and a backing plate 228. The backing plate 228 may function as a blocker plate to enable formation of a gas volume between the gas distribution plate 226 and the backing plate 228. The gas source 222 is connected to the gas distribution plate 226 by a conduit 230.

The gas distribution plate 226, the backing plate 228, and the conduit 230 are generally formed from electrically conductive materials and are in electrical communication with one another. The chamber body 200 is also formed from an electrically conductive material. The chamber body 200 is generally electrically insulated from the showerhead assembly 220. In one embodiment, the showerhead assembly 220 is mounted on the chamber body 200 by an insulator 232.

In one embodiment, the substrate support 215 is also electrically conductive, and the substrate support 215 and the showerhead assembly 220 are configured to be opposing electrodes for generating a plasma 234 of processing gases therebetween during processing of the substrate 120. The controller 145 may be used to monitor the state of the plasma 234 during processing, in one embodiment.

A radio frequency (RF) power source 236 is generally used to generate the plasma 234 between the showerhead assembly 220 and the substrate support 215 before, during and after processing. In one embodiment, the RF power source 236 is coupled to the showerhead assembly 220 by a first output 238a of an impedance matching circuit 239. A second output 238b of the impedance matching circuit 239 is electrically connected to the chamber body 200.

In one embodiment, the processing chamber 105 includes a plurality of RF return devices 240. Each of the RF return devices 240 are coupled between the substrate support 215 and a grounded component of the chamber body 200. Each of the RF return devices 240 may be selectively activated to be open or closed to electrical current. Each of the plurality of RF devices 240 may be spring forms, straps, wires, or cables adapted to provide a RF conductive medium between the substrate support 215 and a grounded component of the chamber body 200 (i.e., a component of the chamber body 200 that is in electrical communication with the RF power source 236).

During processing, one or more processing gas is flowed to the processing volume 210 from the gas source 222 through the showerhead assembly 220. A RF power is applied between the showerhead assembly 220 and the substrate support 215 to generate a plasma 234 from the processing gases for processing the substrate 120.

One embodiment of an RF current path is schematically illustrated by arrows in FIG. 2. The RF current path may be indicative of RF current flow during processing of the substrate 120. The RF current generally travels from a first lead 242a of the RF power source 236 to the first output 238a of the impedance matching circuit 239, then travels along an outer surface of the conduit 230 to a back surface of the backing plate 228, then to a front surface of the gas distribution plate 226. From the front surface of the gas distribution plate 226, the RF current goes through plasma 234 and reaches a top surface of the substrate 120 or the substrate support 215, then through one or more of the plurality of RF return devices 240 to an inner surface 244 of the chamber body 200. From the inner surface 244, the RF current returns to a second lead 242b of the RF power source 236 from the impedance matching circuit 239.

The controller 145 may be coupled to the processing chamber 105 to monitor conditions of the RF power and/or the plasma 234 within the processing chamber 105. The controller 145 may include a central processing unit (CPU), a memory, and support circuits for the CPU that is coupled to the various components of the processing chamber 105 to facilitate control and monitoring of the processes performed therein. The controller 145 may be one of any form of general purpose computer processor that can be used in an industrial setting for controlling various chambers and subprocessors. The memory, or computer-readable medium, may be one or more of readily available memory such as random access memory (RAM), read only memory (ROM), floppy disk, hard disk, or any other form of digital storage, local or remote that is in communication with the CPU. The support circuits are in communication with the CPU for supporting the processor in a conventional manner. These circuits include cache, power supplies, clock circuits, input/output circuitry and subsystems, and the like. Processing recipes and transfer routines as well as metrics indicative of the plasma parameters, such as described herein, is generally stored in the memory as a software routine. The software routine may also be stored and/or executed by a second CPU that is remotely located from the hardware being controlled by the CPU.

In one embodiment, the controller 145 monitors RF related data, such as RF reflected power, direct current voltage (Vdc), voltage peak-to-peak (Vpp), RF current, and other properties of the applied RF power during processing of the substrate 120. The controller 145 may be a database with configurable software modules having sensors that monitor the RF input and/or output to track RF parameters within the processing chamber 105. In one embodiment, the controller 145 may be an automation and equipment engineering system (EES) platform sold by Applied Materials, Inc. as the Applied E3 module, although controllers from other manufacturers could be used.

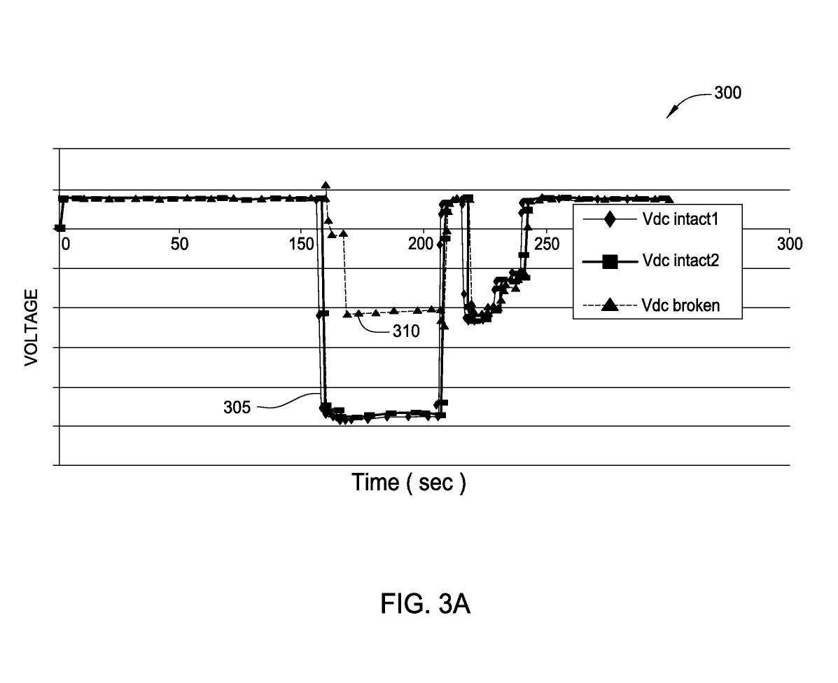

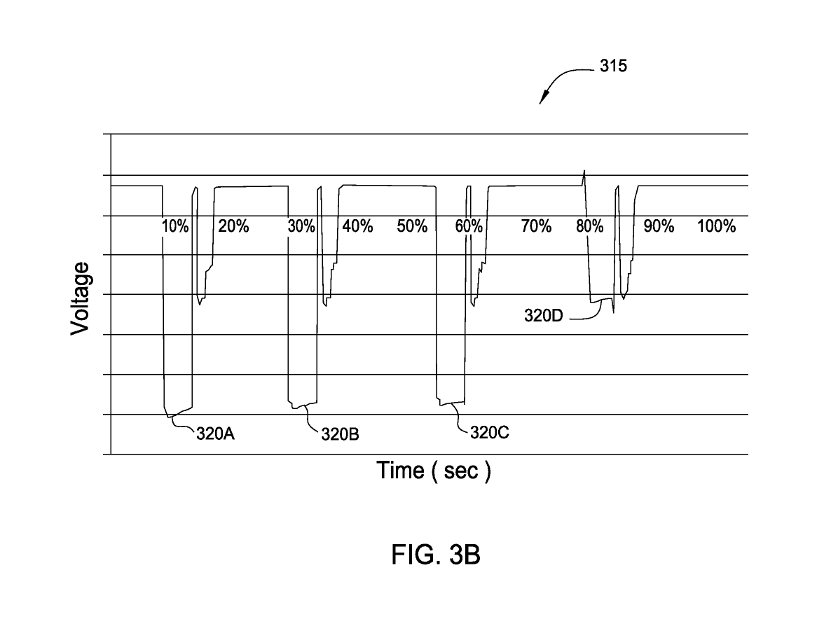

In one embodiment, the controller 145 uses historical RF data (obtained using a manufacturers particular recipe) as a baseline and limits are established such that RF parameters outside of those limits represents breakage and/or contamination due to a previous breakage event. The controller 145 provides the ability to monitor RF related data items such as RF reflected power, Vdc, or Vpp, along with any desired chamber parameter. In one aspect, the changes in RF parameters may be changes in local impedance on each substrate that is recognized by the controller 145. The data collected and/or monitored by the controller 145 may be provided by the impedance matching circuit 239. Using data mining and comparing the signature (i.e., trace(s)) of broken glass to that of intact glass for the whole recipe (one example of which is shown in FIG. 3A), the RF signals are reliable indicators to determine when glass has broken and/or other defects are present. For example, if a previous breakage event contaminates subsequent substrates, a defect in the subsequent substrates may appear. The defects include a short-circuit, arcing, as well as local non-uniformity in the films deposited on the substrates. The defects may affect the final product such that any displays formed thereon will not operate properly.

The following figures are graphical representations of testing results of the defect detection method as described herein.

FIG. 3A is a graph 300 comparing a typical Vdc trace 305 with an abnormal Vdc trace 310 during a deposition process. The ordinate represents voltage and the abscissa represents time (in seconds). The typical Vdc trace 305 represents an undamaged or defect-free substrate (indicated by the “Vdc intact 1” and “Vdc intact 2” traces in this graph) while the abnormal Vdc trace 310 represents a defective substrate (indicated by the “Vdc broken” trace). As shown, a Vdc shift occurs when deposition is performed on the defective substrate indicated by the abnormal Vdc trace 310. A large shift in Vdc may be indicative of a large defect (e.g., a non-uniformity, a crack or chip) while a relatively small shift may be indicative of a smaller defect.

FIG. 3B is a graph 315 showing deposition runs on four substrates represented by traces 320A-320D. The ordinate represents voltage and the abscissa represents time (in seconds). Each of the traces 320A-320C indicates a defect-free substrate based on Vdc parameters (e.g., typical Vdc trace 305). However, trace 320D indicates a defective substrate (e.g., abnormal Vdc trace 310), which is representative of a glass breakage event in the processing system.

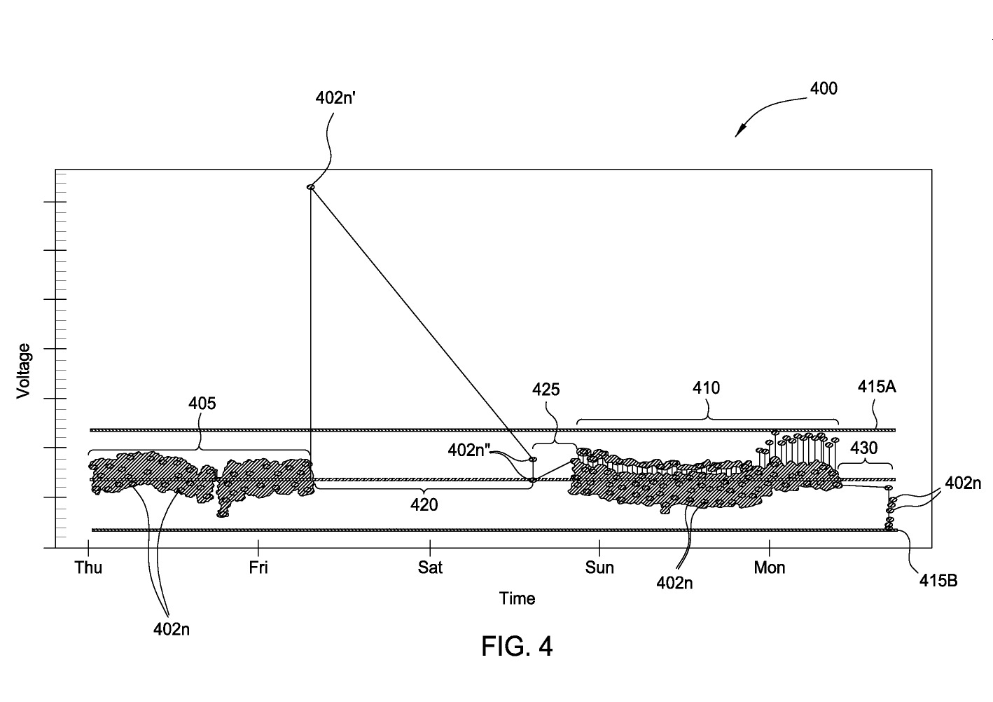

FIG. 4 is a graph 400 showing multiple deposition runs over many days. Each data point represents a substrate that has been plasma processed in a processing system such as the processing chamber 105 of FIG. 2. Each data point is referred to as a substrate 402 n, wherein n represents an integer greater than zero. Regions 405 and 410 are shaded and each region 405 and 410 represent hundreds of substrates 402 n produced over multiple days (the data points are very close to each other and are difficult to show individually given the scale of the graph 400).

According to the defect detection method as described herein, lines 415A and 415B indicate soft limits for a specific recipe. As shown in the graph 400, a substrate 402 n′ is outside of the limit indicated by line 415A and indicates a glass breakage event. When the limit is exceeded, such the excess shown with respect to the substrate 402 n′, an alert may be provided to personnel to shut down the processing system 100. Region 420 indicates a time period where the substrate 402 n′ is removed, and the processing system 100 is inspected and cleaned to remove remnants of the substrate 402 n′. The substrate 402 n′ may be removed through the transfer chamber 115 (shown in FIG. 1) or removed directly from the processing chamber 105 (shown in FIG. 2) such as through the lid 202 (shown in FIG. 2).

Following the inspection and cleaning of the processing system 100, substrates 402 n″ may be plasma processed for qualification. A region 425 indicating a time period for metrology of the substrates 402 n″ may follow the qualification run and the plasma processing resumes at region 410. Region 430 indicates a time period for preventative maintenance (PM) of the processing system 100 and plasma processing of the substrates 402 n resumes after the PM.

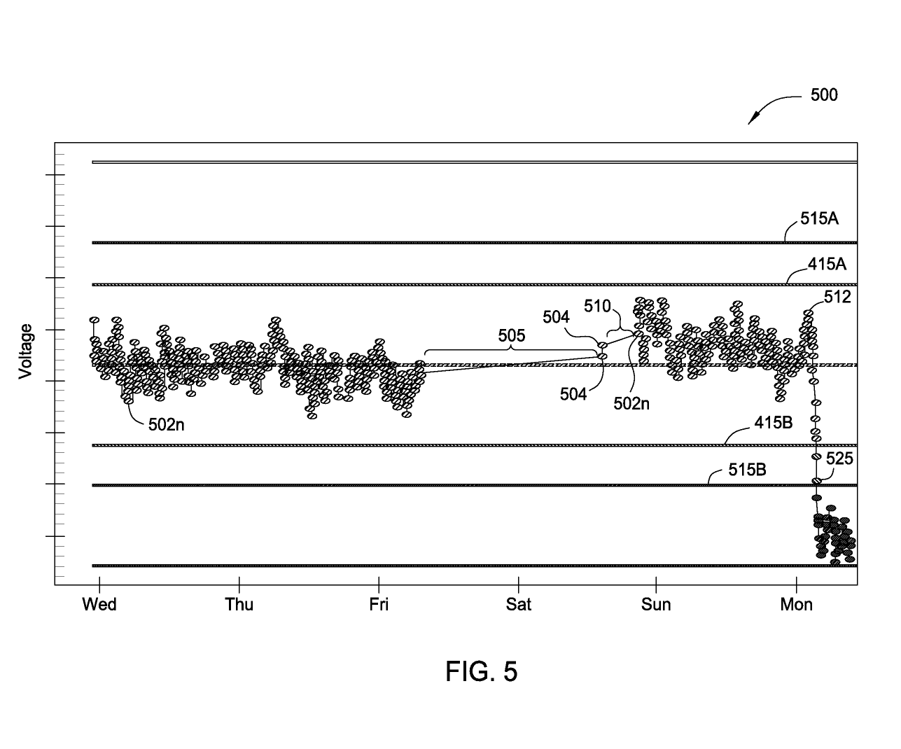

FIG. 5 is a graph 500 showing multiple deposition runs over many days. The ordinate represents voltage and the abscissa represents time (in days). Each data point represents a substrate that has been plasma processed in a processing system such as the processing system 100 of FIG. 1. Each data point is referred to as a substrate 502 n wherein n represents an integer greater than zero, a substrate 504, a substrate 512. Region 505 indicates a time period for PM of the processing system 100 after which substrates 504 are plasma processed for qualification. After a time period 510 for metrology of the substrates 504, processing of substrates 502 n resumes.

The data point indicated by substrate 512 indicates a breakage event. The breakage event according to the graph 500 may be a minor glass break, such as about 5% or less of the surface area of the substrate, as compared to the breakage event shown in the graph 400 of FIG. 4. It has been found that a large shift in the plasma parameters corresponds with a large break, and vice versa. After the breakage event, plasma processing parameters decline in subsequent substrates, and as such, quality of the final product declines. The substrates 502 n represented by data points within the lines 415A and 415B may be deemed as acceptable; however, lines 515A and 515B indicate hard limits where the system should be shut down. For example, substrates between the lines 415B and 515B were tested and passed quality control, but substrates below line 515B were unacceptable and included defects (e.g., the “mura effect”) and were scrapped.

The breakage event shown in FIG. 5 may be a case where glass pieces (small glass shards) were left in the processing chamber after processing the substrate 512, and the product quality suffered. The subsequent decline in the plasma parameters of the substrates processed subsequent to the substrate 512 indicates defects in the films deposited thereon and final testing indicated evidence of the mura effect. In this situation, the fabrication facility could have saved about 120 substrates from scrap if the defect detection method would have been used. For example, the system could have been stopped at substrate 525 and removed from the system, thus saving subsequent substrates from scrap.

Embodiments of the invention provide detection of glass breakage in a processing chamber 105 during deposition by tracking RF process parameters. A controller 145 is utilized to collect chamber data and analyze RF signals for abnormal behavior that deviates from the normal trends according to a specific product recipe.

According to one embodiment, a plasma environment is initiated and maintained in the processing chamber 105. The glass substrate acts as a dielectric and the paths of the ions and the electrons are determined in the chamber for a specific RF power delivery, and these paths through the chamber define the chamber impedance. If a defect appears on the glass substrate, then new paths are formed (a number of them reaching the susceptor directly without going through the glass substrate). The subsequent paths lead to a modified chamber impedance and this impedance difference is tracked to identify if the glass substrate is intact or broken. The controller 145 (shown in FIG. 2) may be provided with a data mining algorithm to track the evolution of RF parameters and thus the impedance during deposition in the processing chamber 105 through a time window.

The deposition and all power lift steps are monitored, and the algorithm utilizes historical data for the same deposition recipe for the given chamber and compares the data to a time weighted average. Limits are then determined based on a review of the historical data, which allows for soft limits that depend on the chamber conditions. When limits are exceeded, an alarm, audible, visual and/or electronic (i.e., e-mail) can be provided to the technicians to alert that there is a problem with the chamber.

The time weighted average of the algorithm serves a dual purpose. The average effectively filters fluctuations that arise from the RF parameter measurements and provides a smooth reading throughout each deposition run. The average also takes into account the chamber condition or “aging” between PM intervals.

The invention uses a relatively inexpensive and non-intrusive method of tracking RF parameter changes in the processing chamber 105 to detect glass breakage in PECVD chambers.

Embodiments of the invention provide a way to minimize the effect of RF parameter measurement fluctuations in the detection of the glass breakage during a deposition recipe run. Embodiments of the invention provide a notification to the relevant parties that glass breakage has occurred in a processing chamber. Early notification is provided to minimize the tool downtime. Broken glass is contained to the processing chamber where the deviation in RF parameters occurs and other chambers, such as the transfer chamber, is not contaminated. This saves considerable time as only one processing chamber will need to be cleaned (as opposed to the whole tool being down for unscheduled maintenance).

By detecting a deviation from the normal (historical) RF parameter values that may be used as a predefined criteria to establish predetermined limits, embodiments of the invention can also detect if small glass pieces have been left in the processing chamber 105 where the deviation occurred. The contamination caused by small glass pieces in a chamber affects the final product quality (i.e., the mura effect). Early notification of leftover small glass pieces in the CVD processing chamber 105 may be beneficial in saving time and minimizing cost of ownership. For example, in a typical display fabrication facility, substrates are only sampled periodically for quality. Full testing only occurs at the end of the line when many substrates may have been processed in a contaminated processing chamber 105 and may exhibit defects caused by the contamination. Thus, at this final check, it is possible that multiple fully processed substrates are scrapped. Utilizing the method described herein provides early identification of a contaminated processing chamber and the chamber may be isolated and cleaned prior to processing other substrates.

While the foregoing is directed to embodiments of the present invention, other and further embodiments of the invention may be devised without departing from the basic scope thereof, and the scope thereof is determined by the claims that follow.

1. A method, comprising:
processing a substrate exposed to a plasma in a processing chamber;
obtaining a metric indicative of a parameter of the plasma during the processing of the substrate; and
determining a defect in the substrate by comparing the metric to a predefined criteria.

2. The method of claim 1, wherein the defect comprises a crack, a break, a chip, a region of non-uniform film on the substrate, or combinations thereof.

3. The method of claim 1, wherein the parameter of the plasma includes reflected radio frequency power, direct current voltage (Vdc), peak-to-peak voltage (Vpp), or combinations thereof.

4. The method of claim 1, further comprising:
removing the substrate from the processing chamber.

5. The method of claim 4, wherein the removing comprises:
removing the substrate from the processing chamber through the transfer chamber.

6. The method of claim 4, further comprising:
inspecting the processing system for pieces of the defective substrate; and
removing the pieces from the processing system.

7. The method of claim 6, further comprising:
resuming operation of the processing chamber.

8. The method of claim 1, wherein the predefined criteria comprises historical data of a processing results from non-defective substrates.

9. A method, comprising:
processing a substrate exposed to a plasma in a processing chamber;
obtaining a metric indicative of a parameter of the plasma during the processing of the substrate;
ceasing the processing when the parameter of the plasma is outside of a predetermined limit indicating a defective substrate; and
removing the defective substrate from the processing system.

10. The method of claim 9, wherein the defect comprises a crack, a break, a chip, a region of non-uniform film on the substrate, or combinations thereof.

11. The method of claim 9, wherein the parameter of the plasma includes reflected radio frequency power, direct current voltage (Vdc), peak-to-peak voltage (Vpp), or combinations thereof.

12. The method of claim 9, wherein the parameter of the plasma includes reflected radio frequency power, direct current voltage (Vdc), peak-to-peak voltage (Vpp), or combinations thereof.

13. The method of claim 12, wherein the predefined criteria comprises historical data of a processing recipe.

14. A method, comprising:
transferring n substrates into one or more chambers in a processing system;
plasma processing each of the n substrates sequentially;
monitoring parameters of the plasma during plasma processing of the n substrates;
ceasing plasma processing when the parameters of one of the n substrates are outside of a predetermined limit indicating a defective substrate; and
removing the defective substrate from the processing system.

15. The method of claim 14, wherein the defect comprises a crack, a break, a chip, a region of non-uniform film on the substrate, or combinations thereof.

16. The method of claim 14, wherein the parameters include reflected radio frequency power, direct current voltage (Vdc), peak-to-peak voltage, or combinations thereof.

17. The method of claim 14, further comprising:
inspecting the processing system for pieces of the defective substrate; and
removing the pieces from the processing system.

18. The method of claim 17, further comprising:
resuming plasma processing of remaining n substrates while monitoring parameters of the plasma during plasma processing of the remaining n substrates.

19. The method of claim 14, wherein the predetermined limit is based on historical data of a processing recipe.

20. The method of claim 19, wherein the historical data includes reflected radio frequency power, direct current voltage (Vdc), peak-to-peak voltage, or combinations thereof.
